(19) United States
(12) Patent Application Publication
(10) Pub. No.: US 2022/0359215 A1
(43) Pub. Date: Nov. 10, 2022

(54) AREA-SELECTIVE ETCHING

(71) Applicant: ASM IP Holding B.V., Almere (NL)

(72) Inventors: René Henricus Jozef Vervuurt, Leuven (BE); Takayoshi Tsutsumi, Nagoya-shi (JP); Masaru Hori, Nissin-shi (JP); Nobuyoshi Kobayashi, Tokyo (JP); Yoshinori Oda, Nagoya-shi (JP); Charles Dezelah, Helsinki (FI)

(21) Appl. No.: 17/724,337

(22) Filed: Apr. 19, 2022

Related U.S. Application Data
(60) Provisional application No. 63/178,223, filed on Apr. 22, 2021.

(51) Int. Cl. H01L 21/3065; H01L 21/02; C23C 16/455

(52) U.S. Cl. CPC H01L 21/3065; H01L 21/0228; C23C 16/45538

(57) ABSTRACT

The current disclosure relates to processes for selectively etching material from one surface of a semiconductor substrate over another surface of the semiconductor substrate. The disclosure further relates to assemblies for etching material from a surface of a semiconductor substrate. In the processes, a substrate comprising a first surface and a second surface is provided into a reaction chamber, an etch-priming reactant is provided into the reaction chamber in vapor phase; reactive species generated from plasma are provided into the reaction chamber for selectively etching material from the first surface. The etch-priming reactant is deposited on the first surface and the etch-priming reactant comprises a halogenated hydrocarbon. The halogenated hydrocarbon may comprise a head group and a tail group, and one or both of them may be halogenated.

### CROSS-REFERENCE TO RELATED APPLICATIONS

This application claims priority to U.S. Provisional Patent Application Ser. No. 63/178,223 filed Apr. 22, 2021 titled AREA-SELECTIVE ETCHING, the disclosure of which is hereby incorporated by reference in its entirety.

### FIELD

The present disclosure relates to methods and apparatuses for the manufacture of semiconductor devices. More particularly, the disclosure relates to methods and systems for selective etching processes.

### BACKGROUND

Dielectric materials, such as silicon oxide and silicon nitride, are used in semiconductor applications as, for example, interlayer dielectrics of interconnects, diffusion barriers and etch hard masks. Conventional etch processes rely heavily on reactive ion etching (RIE). RIE is favorable for the etching of dielectric layers having a thickness in the range of 100 nm or more due to the high etch rate of RIE. Precise control of the etch selectivity and the uniformity is relatively difficult for the etching of thinner dielectric materials. Further, prior art processes may damage underlaying material layers, and the etching may be aspect-ratio dependent. Fluorocarbon layers deposited by plasma-assisted CVD are known in the art to enable a more adjustable etching process. However, such processes lack specificity, and may suffer from process drift. Thus, there is need in the art for further development and fine-tuning of etching processes to enable further scalability and versatility semiconductor device manufacture.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of selectively etching material from a first surface of a substrate relative to a second surface of the substrate. Embodiments of the current disclosure further relate to assemblies for processing a substrate.

Methods of selectively etching material from a first surface of a substrate relative to a second surface of the substrate according to the current disclosure comprise providing a substrate comprising the first surface and the second surface into a reaction chamber and providing an etch-priming reactant into the reaction chamber in vapor phase. The methods further comprise providing reactive species generated from plasma into the reaction chamber for selectively etching material from the first surface. The etch-priming reactant according to the current disclosure is deposited on the first surface; and the etch-priming reactant comprises a halogenated hydrocarbon.

In another aspect, a method of selectively etching material from a first surface of a substrate relative to a second surface of the substrate comprises an etch process comprising forming an etch-priming layer on the first surface using a halosilane compound comprising an aromatic hydrocarbon.

The current disclosure further relates to an assembly for processing a substrate. The assembly for processing a substrate comprises a reaction chamber constructed and arranged to hold the substrate, an etch-priming reactant source constructed and arranged to contain and evaporate the etch-priming reactant, a plasma generator for generating plasma, a plasma reactant source for providing a gas to the plasma generator; and a reactant injection system constructed and arranged to provide an etch-priming reactant and plasma from the plasma generator into the reaction chamber in vapor phase.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings:

FIGS. 1A and 1B are block diagrams depicting an exemplary embodiment of a method according to the current disclosure.

FIG. 2 depicts an exemplary embodiment of a method according to the current disclosure in schematic form.

FIG. 3 presents an embodiment of an assembly for processing a substrate according to the current disclosure.

### DETAILED DESCRIPTION

The description of exemplary embodiments of methods and assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

### General

In an aspect, a method of selectively etching material from a first surface of a substrate relative to a second surface of the substrate is disclosed. The method comprises providing a substrate comprising the first surface and the second surface into a reaction chamber, providing an etch-priming reactant into the reaction chamber in vapor phase, and providing reactive species generated from plasma into the reaction chamber for selectively etching material from the first surface. The etch-priming reactant is deposited on the first surface; and the etch-priming reactant comprises a halogenated hydrocarbon.

The etch process according to the current disclosure may be termed atomic layer etching. Atomic layer etching (ALE) is a comparable technique to ALD, in that separated pulses of one or more reactants are utilized. However, rather than depositing material as in ALD, in ALE thin layers of material are controllably removed using sequential reaction steps. In some embodiments the sequential reaction steps are self-limiting. In contrast to conventional continuous etching, ALE typically utilizes a one or more etching cycles to remove material. One or more etching cycles may be provided in an ALE process. In some embodiments, the selective etching process according to the current disclosure is a self-limiting process.

Selective etching processes according to the current disclosure may be used to remove material from a substrate surface selectively. The material to be removed may be referred to as the etch-target material or target material. In some embodiments, the target material may be a material comprised in the substrate, or deposited on the substrate. In some embodiments, the target material has been deposited on the substrate on purpose. In some embodiments, the target material may be an unwanted contaminant on the substrate surface. For example, in some embodiments the target material to be etched is parasitic material grown unwantedly from an area-selective deposition process.

Selectivity in etching may be described as an etch ratio, which is the ratio of etch rate of the material on the first surface relative to the etch rate of the material on the second surface. In some embodiments, the etch selectivity of the process according to the current disclosure is about 1.5 or greater. For example, etch selectivity may be from about 1.5 to about 1,000, such as from about 1.5 to about 500, or from about 1.5 to about 200, or from about 1.5 to about 100, or from about 1.5 to about 50, or from about 1.5 to about 50, such as about 2, about 3, about 5, about 10 or about 20. In some embodiments, etch selectivity may be from about 2 to about 1,000, such as from about 5 to about 1,000, or from about 10 to about 1,000, or from about 50 to about 1,000, or from about 100 to about 1,000, or from about 500 to about 1,000. In some embodiments, etch selectivity may be from about 2 to about 500, such as from about 5 to about 500, or from about 10 to about 200, or from about 50 to about 200, or from about 20 to about 100, or from about 10 to about 100. In some embodiments, the second surface (i.e., material of the second surface) is not etched. In some embodiments, the second surface is substantially not etched. In some embodiments, the second surface is etched to a lesser extent than the first surface.

In some embodiments, the current selective etching method is used as a part of a vapor deposition process. The deposition process may be selective. In some embodiments, a selective etching process may be carried out at one, two or more intervals in a vapor deposition process. In some embodiments a selective etching step may be carried out following one or more deposition cycles in a cyclic vapor deposition process. For example, a selective etching step may be carried out every nth deposition cycle in a cyclic vapor deposition process like an atomic layer deposition (ALD) process, where n is an integer. In some embodiments a selective etch step may be carried out after every cycle in a cyclic vapor deposition process such as an ALD process.

In some embodiments, the selective etching process is a cyclic etching process. In some embodiments a substrate is contacted with reactive species as described herein for a sufficient time to achieve the desired level of etching in one step. In some embodiments an etch process is repeated at least once. In other words, providing an etch-priming reactant into the reaction chamber and providing reactive species into the reaction chamber may be repeated at least once. Providing an etch-priming reactant into the reaction chamber and providing reactive species into the reaction chamber may be termed an etching cycle. An etching cycle may comprise purging the reaction chamber after providing an etch-priming reactant and/or after providing reactive species into the reaction chamber. The number of etching cycles depends on the desired etching depth, and the etch rate of the process. The latter may be adjusted through process parameters, such as ion energy (plasma power, bias power and pressure) and substrate temperature. In some embodiments, etching thickness of from about 0.5 nm to about 50 nm may be used.

In some embodiments, the method comprises at least 5 etching cycles. In some embodiments, the method comprises at least 10, or at least 50 etching cycles. In some embodiments, the method comprises at least 100 etching cycles. In some embodiments, the method comprises at least 200, or at least 300, or at least 500 etching cycles. In some embodiments, the method comprises from about 5 to about 500 etching cycles. In some embodiments, the method comprises from about 5 to about 100 etching cycles, such as from about 5 to about 50 etching cycles, or from about 10 to about 100 etching cycles, or from about 50 to about 100 etching cycles. In some embodiments, the method comprises from about 50 to about 500 etching cycles, such as from about 50 to about 200 etching cycles, or from about 100 to about 500 etching cycles. In some embodiments, the method comprises from about 200 to about 500 etching cycles.

An etching cycle may comprise a phase in which a substrate in a reaction chamber is contacted with a vapor-phase etch-priming reactant (also referred to as a reactant or etch reactant). In some embodiments, an etching cycle and excess etching agent and reaction byproducts are subsequently removed from the reaction chamber. In some embodiments this etching cycle can be repeated multiple times. In some embodiments an etching cycle is repeated multiple times sequentially. In some embodiments an etching cycle is repeated at intervals, for example at one, two or more intervals in another deposition process such as an area selective deposition process.

In some embodiments, the target material is etched at a rate from about 0.1 Å to about 1 Å per etch cycle, such as at a rate from about 0.1 Å to about 0.7 Å per etch cycle. In some embodiments, the target material is etched at a rate from about 0.1 Å to about 0.5 Å per etch cycle, or at a rate from about 0.2 Å to about 0.5 Å per etch cycle. In some embodiments, the target material is etched at a rate from about 0.1 Å to about 0.3 Å per etch cycle.

In some embodiments, the etch-priming reactant and the reactive species are provided into the reaction chamber alternately and sequentially. In some embodiments, the reaction chamber is purged after providing etch-priming reactant and/or after providing reactive species into the reaction chamber.

In the method according to the current disclosure, the etch-priming reactant may be in vapor phase when it is in a reaction chamber. The etch-priming reactant may be partially gaseous or liquid, or even solid at some points in time prior to being provided in the reaction chamber. In other words, an etch-priming reactant may be solid, liquid or gaseous, for example, in a source vessel or other receptacle before delivery in a reaction chamber. Various means of bringing the reactant in to gas phase can be applied when delivery into the reaction chamber is performed. Such means may include, for example, heaters, vaporizers, gas flow or applying lowered pressure, or any combination thereof. Thus, the method according to the current disclosure may comprise heating the etch-priming reactant prior to providing it to the reaction chamber. In some embodiments, etch-priming reactant is heated to at least 30° C., or to at least 40° C., or to at least 50° C. or to at least 100° C. in a source vessel. An injector system for injecting the etch-priming reactant into a reaction chamber may be heated to improve the vapor phase delivery of the etch-priming reactant to the reaction chamber. In some embodiments, the etch-priming reactant is not heated. A suitable temperature may depend on the properties of the etch-priming reactant in question, such as temperature sensitivity and vapor pressure. In some embodiments, the process according to the current disclosure is performed at a temperature from about 20° C. to about 120° C. Thus, the temperature in a reaction chamber may be, for example, from about 20° C. to about 100° C., or from about 20° C. to about 60° C.

In this disclosure, “gas” can include material that is a gas at normal temperature and pressure (NTP), a vaporized solid and/or a vaporized liquid, and can be constituted by a single gas or a mixture of gases, depending on the context. The etch-priming reactant may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

The term “purge” or “purging” may refer to a procedure in which vapor phase reactants and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of reactants, such as etch-priming reactant and/or reactive species provided in the reaction chamber. Purging may avoid or at least reduce gas-phase interactions between gases present in the reaction chamber. It shall be understood that a purge can be effected either in time or in space, or both. For example in the case of temporal purges, a purge step can be used, e.g., in the temporal sequence of providing a first reactant, such as an etch-priming reactant, into a reactor chamber, providing a purge gas into the reactor chamber, and providing a second reactant, such as reactive species generated from plasma, into the reactor chamber, wherein the substrate on which a layer is deposited does not move. In the case of spatial purge, a purge step can take the following form: moving a substrate from a first location to which a first reactant is continually supplied, through a purge gas curtain, to a second location to which a second reactant is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where high aspect ratio structures or other structures with complex surface morphology are processed.

A reaction chamber according to the current disclosure may be part of a cluster tool in which different processes are performed to form an integrated circuit. In some embodiments, a flow-type reactor is utilized. In some embodiments, a cross-flow reactor is used. In some embodiments, a showerhead-type reactor is utilized. In some embodiments, the reaction chamber may be a space-divided reactor. In some embodiments, the reaction chamber may be a batch reactor for manufacturing multiple substrates simultaneously.

In the selective etching process according to the current disclosure, the first surface and the second surface are chemically distinct. That is, the first surface and the second surface differ from each other chemically in a manner that they are distinguishable from each other in the current process.

As used herein, the term substrate may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

### First Surface

In some embodiments, the first surface (i.e., material of the first surface) comprises oxygen. In some embodiments, the material of the second surface does not contain oxygen. In some embodiments, the material of the first surface comprises an oxide. In some embodiments, the material of the second surface does not contain an oxide. In some embodiments, the material of the first surface comprises, consists essentially of, or consists of a metal oxide or a semimetal oxide. In some embodiments, the metal oxide is a transition metal oxide. Many metals may form oxides in various oxidation states, and the term oxide as used herein encompasses all suitable oxidation states. In some embodiments, the metal or semimetal oxide is selected from a group consisting of hafnium oxide, zirconium oxide, ruthenium oxide, rhenium oxide, niobium oxide, nickel oxide, cobalt oxide, molybdenum oxide, tungsten oxide, titanium oxide, vanadium oxide, chromium oxide, manganese oxide, rhodium oxide, palladium oxide, platinum oxide, copper oxide or silver oxide, aluminum oxide and silicon oxide. In some embodiments, the first surface comprises, consist essentially of, or consist of silicon oxide (such as SiO₂). The first surface may comprise substantially only silicon oxide, such as SiO₂. The first surface may comprise doped silicon oxide, such as boron-doped silicon oxide or phosphorus-doped silicon oxide. In some embodiments, the first surface comprises, consists essentially of, or consists of silicon oxycarbide (SiOC). In some embodiments, the first surface comprises a silicon oxide layer. A silicon oxide layer is a layer characterized or recognized as a silicon oxide layer. It may include other elements such as nitrogen, carbon, hydrogen, etc. and impurities to the extent that such elements do not materially change the characteristics of the silicon oxide layer. A silicon oxide layer may include not only SiO₂ layers, but also SiOC layers, SiON layers, SiOCN layers, or the like. In some embodiments, target material is silicon oxide, silicon oxycarbide, silicon oxycarbonitride or silicon oxynitride. Thus, silicon oxide, silicon oxycarbide, silicon oxycarbonitride or silicon oxynitride may be selectively etched by the method according to the current disclosure.

In some embodiments a first surface comprising metal oxide is an oxidized surface of a metallic material. In some embodiments a first surface comprising metal oxide is created by oxidizing at least the surface of a metallic material using oxygen compound, such as compounds comprising O₃, H₂O, H₂O₂, O₂, oxygen atoms, plasma or radicals or mixtures thereof. In some embodiments, a first surface comprising a metal oxide is a native oxide formed on a metallic material.

### Second Surface

In some embodiments, the second surface comprises nitrogen. In some embodiments, the first surface does not contain nitrogen. In some embodiments, the second surface comprises a nitride. In some embodiments, the first surface does not comprise a nitride. In some embodiments, the second surface comprises nitrogen and hydrogen. In some embodiments, the second surface comprises, consists essentially of, or consists of silicon nitride. In some embodiments, the second surface comprises a silicon carbonitride (SiCN).

In this disclosure, a SiN is a layer characterized or recognized as a silicon nitride layer which may include other elements such as oxygen, carbon, hydrogen, etc. and impurities to the extent that such elements do not materially change the characteristics of the silicon nitride layer. Thus, a SiN layer may include not only SiN layers, but also SiNC layers, SiNO layers, SiNCO layers, or the like, depending on the process recipe, wherein these layer names are commonly accepted abbreviations in the art, indicating merely the layer types (indicating simply by primary constituent elements), in a non-stoichiometric manner unless described otherwise. In some embodiments, a SiN has a dielectric constant of about 2 to 10, typically about 4 to 8. In some embodiments, second surface is not a metal oxide surface. In some embodiments, the second surface is not a semimetal oxide surface. In some embodiments, the second surface does substantially not comprise carbon. In some embodiments, the second surface does substantially not comprise oxide.

### Combinations of First Surface and Second Surface

The first surface and the second surface are chemically distinct. In other words, they display difference in their chemical properties. However, they both can have one or more same constituent. For example, both may comprise silicon, oxygen and/or nitrogen. Even if both surfaces share one or more constituent element, there other constituent of the surface and/or the form in which the element in question is present differ resulting in chemical distinctness. In some embodiments, the first surface and the second surface comprise silicon. In some embodiments, the first surface comprises silicon oxide and the second surface comprises silicon nitride. In some embodiments, the first surface consists essentially of, or consists of silicon oxide and the second surface consists essentially of, or consists of silicon nitride. In some embodiments, the first surface comprises hydroxyl (—OH) groups available for interacting with an etch-priming reactant. In some embodiments, the second surface is void or substantially void of hydroxyl groups available for interacting with an etch-priming reactant. In some embodiments, the second surface comprises amine (—NH₂) groups available for interacting with an etch-priming reactant. In some embodiments, the first surface is void or substantially void of amine groups available for interacting with an etch-priming reactant. In some embodiments, the first surface consists essentially of silicon oxide, and silicon oxide is the etch target material.

In some embodiments, the etch-priming reactant is not deposited on the second surface. In some embodiments, the etch-priming reactant is substantially not deposited on the second surface. In some embodiments, the etch-priming reactant is preferentially deposited on the first surface. In some embodiments, the etch-priming reactant is deposited only, or substantially only on the first surface.

Without limiting the current disclosure to any specific theory, the etch-priming reactant may be selected so that it has higher preference for interacting with hydroxyl groups than amine groups, which may lead to the etch-priming reactant being selectively deposited on the first surface.

The first surface and the second surface may each independently be a layer deposited on a substrate. However, they, and especially the first surface may comprise, consist essentially of, or consist of substrate bulk material.

### Etch-Priming Reactant

An etch-priming reactant according to the current disclosure may be deposited on the first surface. The etch-priming reactant may enhance the etching of the first surface. Without limiting the current disclosure to any specific theory, the etch-priming reactant may enhance the already-existing difference in etch rate between the first surface and the second surface so that the first surface is etched faster than the second surface. Alternatively, the etch-priming reactant may make the first surface more sensitive to etching, and create a difference in etch rate between the first surface and the second surface that is not otherwise present. In some embodiments, the first surface may even be more resistant to etching in the absence of an etch-priming reactant. In some embodiments, etch-priming reactant chemisorbs on the first surface. In some embodiments, the etch-priming reactant forms a self-assembled monolayer on the first surface. In some embodiments, the etch-priming reactant comprises a head group for contacting the substrate. In some embodiments, the head group causes chemisorption of the etch-priming reactant on the substrate surface. In some embodiments, the head group is halogenated.

An etch-priming reactant according to the current disclosure comprises a halogenated hydrocarbon. The hydrocarbon may comprise additional functional groups, for example, comprising oxygen, silicon, sulfur or phosphorus. The size of the etch-priming reactant molecule may vary broadly. The etch-priming reactant may comprise 24 carbon atoms. In some embodiments, the etch-priming reactant comprises 2 to 20 carbon atoms. In some embodiments, the etch-priming reactant comprises 2 to 16 carbon atoms. In some embodiments, the etch-priming reactant comprises 2 to 12 carbon atoms. In some embodiments, the etch-priming reactant comprises 2 to 10, or 2 to 8 carbon atoms.

The head group may comprise one or more halogen atoms. In some embodiments, the head group comprises a third-row semimetal or a non-metal and a halogen. By “third row” is herein meant the third row of the periodic table of elements. In some embodiments, the head group comprises an oxygen atom. In some embodiments, the oxygen atom is connected to a carbon atom, silicon atom, phosphorus atom, or to a sulfur atom. In some embodiments, the oxygen atom is connected to a carbon atom, silicon atom, phosphorus atom, or to a sulfur atom through a double bond. The halogen in a head group may be selected from a group consisting of F, Cl, Br and I.

In some embodiments, the head group contains a third-row semimetal or non-metal. In some embodiments, the third-row semimetal or non-metal is not a halogen. In some embodiments, there is one third-row semimetal or non-metal atom present in the head group. However, embodiments may be envisaged in which there are two or more third-row semimetal or non-metal atoms in a head group. One or more halogen atoms may be attached to the third-row semimetal or non-metal atom. In some embodiments, the third-row semimetal or non-metal is selected from a group consisting of silicon, phosphorus and sulfur.

In some embodiments, the halogens attached to the silicon atom are chlorine atoms. In some embodiments, the head group comprises an oxygen atom connected to the rest of the molecule through a double bond. In some embodiments, the head group comprises an acyl halide. In some embodiments, the head group comprises a sulfinyl halide. In some embodiments, the head group comprises a phosphonyl dihalide. In some embodiments, the head group comprises a diphenyl phosphinic halide. In some embodiments, the head group comprises an amine group. In some embodiments, the amine is a primary amine. In some embodiments, the amine is a secondary amine. In some embodiments, the amine is a tertiary amine.

In some embodiments, the etch-priming reactant comprises a head group and a tail group. A head group may be able to bind to the first surface. The head group may comprise halogen atoms. The tail group may comprise halogen atoms. In some embodiments, the head group and the tail group comprise halogen atoms. In some embodiments, only the tail group comprises halogen atoms. The halogen atoms of the tail group may bring about or enhance etching material of the first surface. In some embodiments, the tail group comprises one or more fluorine atoms for etching the material of the first surface.

In some embodiments, the head group comprises a substituted silane. In some embodiments, the substituted silane comprises one, two or three halogens attached to a silicon atom. Thus, in some embodiments, the head group comprises a halosilane. In some embodiments, the head group is a halosilane group. In some embodiments, the halogen in the silane group is selected from a group consisting of F, Cl, Br and I. In some embodiments, the silane group is monohalogenated. In some embodiments, the silane group is dihalogenated. In some embodiments, the silane group is trihalogenated. In some embodiments, the silane group is a trichlorosilane group. In some embodiments, the silane group is a dichlorosilane group. In some embodiments, the silane group is a tribromosilane group. In some embodiments, the silane group is a dibromosilane group. In some embodiments, the silane group is a trifluorosilane group. In some embodiments, the silane group is a difluorosilane group. In some embodiments, the silane group is a triiodosilane group. In some embodiments, the silane group is a diiodosilane group.

The silane group may be directly attached to an aromatic ring. The silane group and the aromatic ring may both be halogenated. For example, the aromatic ring may be fluorinated, and the silane substituent may be chlorinated. In some embodiments, the silane group is attached to an aromatic ring through an aliphatic linker. The linker may be a C1 to C4 carbon chain. The linker may be linear or branched. The silane may be attached to an aliphatic hydrocarbon. In other words, the etch-priming reactant comprises a silane group and a linear or branched hydrocarbon, and no aromatic rings. The silane and the aliphatic hydrocarbon may be multiply halogenated.

In some embodiments, the head group comprises an acyl halide group. In some embodiments, the head group is an acyl halide group (X(C═O)—C, wherein X is F, Cl, Br or I). In some embodiments, the acyl halide is an acyl chloride. In some embodiments, the acyl halide is an acyl fluoride. In some embodiments, the acyl halide is an acyl bromide. In some embodiments, the acyl halide is an acyl iodide. In some embodiments, the head group comprises a sulfinyl halide. In some embodiments, the head group is a sulfinyl halide (X(S═O)—C, wherein X is F, Cl, Br or I). In some embodiments, the sulfinyl halide is a sulfinyl chloride. In some embodiments, the sulfinyl halide is a sulfinyl fluoride. In some embodiments, the head group comprises a sulfonyl halide X(S(═O)₂)—C, wherein X is F, Cl, Br or I). In some embodiments, the head group is a sulfonyl halide. In some embodiments, the sulfonyl halide is a sulfonyl chloride. In some embodiments, the sulfonyl halide is a sulfonyl fluoride. In some embodiments, the head group comprises a phosphonic dihalide (X₂(P═O)—C, wherein X is F, Br or I). In some embodiments, the head group is a phosphonic dihalide. In some embodiments, the phosphonic dihalide is a phosphonic dichloride. In some embodiments, the phosphonic dihalide is a phosphonic difluoride. In some embodiments, the phosphonic acid is a phosphonic dibromide. In some embodiments, the head group comprises a diphenyl phosphinic halide, such as a diphenyl phosphinic chloride.

The head group is connected to the tail group. The tail group may comprise a halogenated hydrocarbon. The halogenated hydrocarbon may be a C1 to C10 linear or branched hydrocarbon. The halogenated hydrocarbon may be an aromatic hydrocarbon. In some embodiments, the halogenated hydrocarbon is a C1 to C3 hydrocarbon. In some embodiments, the halogenated hydrocarbon is an unsaturated hydrocarbon. Without limiting the current disclosure to any specific theory, a shorted hydrocarbon chain may result in less carbon deposition on the substrate during the process. In some embodiments, the head group is directly connected to a tail group. Thus, a halogenated hydrocarbon attached to the head group is the tail group. A tail group may comprise a halogenated hydrocarbon. In an example, the diphenyl phosphinic halide, the tail group may be connected to the head group through one of the phenyl rings.

An etch-priming reactant according to the current disclosure comprises a halogenated hydrocarbon. The halogenated hydrocarbon may constitute a tail group. In some embodiments, the tail group comprises a halogenated hydrocarbon. In some embodiments, the tail group is a halogenated hydrocarbon. The halogenated hydrocarbon may comprise a C1 to C12 hydrocarbon. Thus, the hydrocarbon may contain from 1 to 12 carbon atoms. For example, the hydrocarbon may comprise 2 carbon atoms, 3 carbon atoms, 4 carbon atoms, 5 carbon atoms, 6 carbon atoms, or 7 carbon atoms, or 8 carbon atoms, or 9 carbon atoms or 10 carbon atoms, or 11 carbon atoms. In some embodiments, all the carbon atoms of the halogenated hydrocarbon are halogenated. In some embodiments, one carbon atom of the halogenated hydrocarbon is not halogenated. Unless otherwise indicated, the term “halogenated hydrocarbon” refers to a hydrocarbon comprising at least one halogen atom. Thus, a halogenated hydrocarbon contains at least one carbon atom with at least one halogen atom attached to it. A halogenated carbon atom may contain one, two or, at the end of a carbon chain, three halogen atoms. In some embodiments, two carbon atoms of the halogenated hydrocarbon are not halogenated. In some embodiments, three carbon atoms of the halogenated hydrocarbon are not halogenated. In some embodiments, four carbon atoms of the halogenated hydrocarbon are not halogenated. In some embodiments, the halogenated hydrocarbon comprises one halogenated carbon atom. In some embodiments, the halogenated hydrocarbon comprises two halogenated carbon atoms. In some embodiments, the halogenated hydrocarbon comprises three halogenated carbon atoms. In some embodiments, the halogenated hydrocarbon comprises four halogenated carbon atoms. In some embodiments, the halogenated hydrocarbon comprises five halogenated carbon atoms. In some embodiments, the halogenated hydrocarbon comprises six halogenated carbon atoms. In some embodiments, the halogenated hydrocarbon comprises seven halogenated carbon atoms.

In some embodiments, the halogenated hydrocarbon is selected from fluorinated hydrocarbons, chlorinated hydrocarbons, brominated hydrocarbons and iodinated hydrocarbons or mixtures thereof. In some embodiments, the halogenated hydrocarbon contains fluorine (F) and chlorine (Cl). In some embodiments, the halogenated hydrocarbon contains F and bromide (Br). In some embodiments, the halogenated hydrocarbon contains F and iodine (I). In some embodiments, the halogenated hydrocarbon contains Cl and Br. In some embodiments, the halogenated hydrocarbon contains Cl and I. In some embodiments, the halogenated hydrocarbon contains Br and I.

In some embodiments, the halogenated hydrocarbon comprises a halogenated aromatic hydrocarbon. In some embodiments, the halogenated hydrocarbon comprises an aromatic hydrocarbon, wherein the aromatic ring is halogenated. In some embodiments, all the halogenated carbon atoms of the halogenated hydrocarbon are in the aromatic ring. The aromatic ring may be a five-membered ring. The aromatic ring may be a six-membered ring. The aromatic ring may be a fused aromatic ring. The aromatic ring may be a furanyl ring. The aromatic ring may be a pyrrolyl ring. The aromatic ring may be a phenyl ring.

The aromatic ring may be multiply halogenated. In some embodiments, the aromatic ring comprises five halogen atoms. In some embodiments, the aromatic ring comprises four halogen atoms. In some embodiments, the aromatic ring comprises three halogen atoms. In some embodiments, the aromatic ring comprises two halogen atoms. In some embodiments, the aromatic ring comprises one halogen atom. In some embodiments, the aromatic ring is multiply fluorinated. In some embodiments, the aromatic ring is multiply chlorinated. In some embodiments, the aromatic ring is multiply brominated. In some embodiments, the aromatic ring is multiply iodinated. In some embodiments, the halogenated hydrocarbon comprises a pentafluorophenyl group. In some embodiments, the halogenated hydrocarbon comprises a pentachlorophenyl. In some embodiments, the halogenated hydrocarbon comprises a pentabromophenyl. In some embodiments, the halogenated hydrocarbon comprises a pentaiodophenyl. In some embodiments, the aromatic ring comprises another substituent in addition to halogens.

In some embodiments, the halogenated hydrocarbon comprises an aliphatic hydrocarbon. In some embodiments, the aliphatic hydrocarbon is a linear hydrocarbon. In some embodiments, the aliphatic hydrocarbon is a branched hydrocarbon. In some embodiments, the halogenated hydrocarbon is an aliphatic hydrocarbon. In other words, in some embodiments, the halogenated hydrocarbon does not comprise aromatic moieties. The aliphatic hydrocarbon may be a C1 to C12 hydrocarbon, for example a C2 hydrocarbon, a C3 hydrocarbon, a C4 hydrocarbon, a C5 hydrocarbon, a C6 hydrocarbon, a C7 hydrocarbon, a C8 hydrocarbon or a C9 hydrocarbon. The aliphatic halogenated hydrocarbon may be multiply halogenated. One or more of the carbon atoms of an aliphatic hydrocarbon may be bonded to one, two or three halogen atoms. In some embodiments, the aliphatic hydrocarbon comprises two halogen atoms attached to the same or different carbon atoms. In some embodiments, the aliphatic hydrocarbon comprises three halogen atoms attached to the same or different carbon atoms. In some embodiments, the aliphatic hydrocarbon comprises four halogen atoms attached to two or more carbon atoms. In some embodiments, the aliphatic halogenated hydrocarbon comprises five halogen atoms attached to two or more carbon atoms. In some embodiments, the aliphatic hydrocarbon comprises six halogen atoms attached to three or more carbon atoms. In some embodiments, the aliphatic hydrocarbon comprises seven halogen atoms attached to three or more carbon atoms. In some embodiments, the aliphatic hydrocarbon comprises eight halogen atoms attached to four or more carbon atoms. In some embodiments, the aliphatic hydrocarbon comprises nine halogen atoms attached to four or more carbon atoms. In some embodiments, the aliphatic hydrocarbon comprises ten halogen atoms attached to five or more carbon atoms. In some embodiments, the aliphatic hydrocarbon comprises eleven halogen atoms attached to five or more carbon atoms. In some embodiments, the aliphatic hydrocarbon comprises twelve halogen atoms attached to six or more carbon atoms. In some embodiments, the aliphatic hydrocarbon comprises thirteen halogen atoms attached to six or more carbon atoms. In some embodiments, the aliphatic hydrocarbon comprises fourteen halogen atoms attached to seven or more carbon atoms. In some embodiments, the aliphatic hydrocarbon comprises fifteen halogen atoms attached to seven or more carbon atoms. In some embodiments, the aliphatic hydrocarbon comprises sixteen halogen atoms attached to eight or more carbon atoms. In some embodiments, the aliphatic hydrocarbon comprises seventeen halogen atoms attached to eight or more carbon atoms. In some embodiments, the aliphatic hydrocarbon may comprise eighteen, nineteen, twenty or more halogen atoms similarly arranged.

In some embodiments, all but one carbon atom of the aliphatic hydrocarbon are halogenated. In some embodiments, all but two carbon atoms of the aliphatic hydrocarbon are halogenated. In some embodiments, all but three carbon of the aliphatic hydrocarbon are halogenated. In some embodiments, all but one carbon atom of the aliphatic hydrocarbon are fully halogenated. In some embodiments, all but two carbon atoms of the aliphatic hydrocarbon are fully halogenated. In some embodiments, all but three carbon of the aliphatic hydrocarbon are fully halogenated. By a fully halogenated carbon atom is meant a carbon atom that does not contain any bonds to hydrogen, but only to halogen atoms and other carbon atoms.

The halogen atoms of the aliphatic hydrocarbon may be the same halogen or a different halogen. In some embodiments, the aliphatic hydrocarbon is fluorinated. In some embodiments, the aliphatic hydrocarbon is chlorinated. In some embodiments, the aliphatic hydrocarbon is brominated. In some embodiments, the aliphatic hydrocarbon is iodinated.

In some embodiments, the etch-priming reactant may have the Formula (Ia),

Y₃Si(CHₐX_{b})ₙCH_{c}X_{d}, Formula (Ia)

where Y is selected from a group consisting of Cl, F, Br, I and NR₂, wherein R is H or a C1 to C3 alkyl, X is selected from a group consisting of Cl, F, Br and I, a is 0, 1 or 2, and b is 2—a, c is 0, 1, 2 or 3, d is 3—c, and n is an integer from 0 to 11. a and b are independently selected for each carbon. X and Y may be the same or different. In some embodiments, X and Y are F. In some embodiments, X and Y are Cl. In some embodiments, X is F and Y is Cl. In some embodiments, X is F and Y is Cl. In some embodiments, X is F and Y is Br.

Thus, in some embodiments, the etch-priming reactant may have the Formula (Ib),

Y₃Si(CH₂)ₐ(CX₂)_{b}CH_{c}X_{d}, Formula (Ib)

where Y is selected from a group consisting of Cl, F, Br, I and NR₂, wherein R is H or a C1 to C3 alkyl, X is selected from a group consisting of Cl, F, Br and I, a and b are integers from 0 to 11, with the proviso that a+b≤11, c is 0, 1, 2 or 3, d is 3-c. X and Y may be the same or different. In some embodiments, X is F and Y is Cl. In some embodiments, X is F and Y is Br. In some embodiments, X is F and Y is I. In some embodiments, X is Cl and Y is Br. In some embodiments, X is Cl and Y is F. In some embodiments, X is F and Y is Br. In some embodiments, X is F and Y is F. In some embodiments, X is Cl and Y is Cl. In some embodiments, a is 0, b is 0, X is F and Y is NH₂. In some embodiments, a is 0, b is 0, X is F and Y is N(CH₃)₂. For example, the etch-priming reactant may comprise trichloro(1H,1H,2H,2H-perfluorooctyl)silane, i.e., Cl₃Si(CH₂)₂(CF₂)₅CF₃ (CAS nro 78560-45-9). In some embodiments, the etch-priming reactant may comprise [2-(perfluoropentyl)ethyl]trichlorosilane, i.e., Cl₃Si(CH₂)₂(CF₂)₄CF₃ (CAS nro 229499-00-7). In some embodiments, the etch-priming reactant may comprise [2-(perfluorobutyl)ethyl]trichlorosilane, i.e., Cl₃Si(CH₂)₂(CF₂)₃CF₃ (CAS no. 78560-47-1).

In some embodiments, the etch-priming reactant may have a structure according to Formula (II),

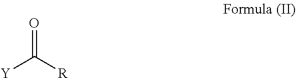

In some embodiments, the etch-priming reactant may have a structure according to Formula (III),

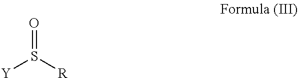

In some embodiments, the etch-priming reactant may have a structure according to Formula (IV),

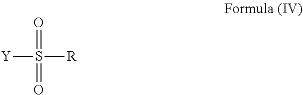

In some embodiments, the etch-priming reactant may have a structure according to Formula (V),

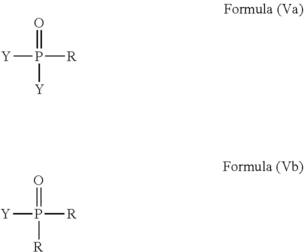

In Formulae (II) to (Vb), R is a C1 to C12 linear, branched, cyclic or aromatic hydrocarbon as described above, Y is selected from a group consisting of Cl, F, Br, I and NR′₂, wherein R′ is H or a C1 to C3 alkyl; and X is selected from a group consisting of Cl, F, Br and I. R may comprise one or more halogens, attached to one or more carbons, the halogens being selected from a group consisting of F, Cl, Br and I. In some embodiments, the one or more halogen atoms in in R is F and Y is Cl. X and Y may be the same or different. In some embodiments, the one or more halogens in R is F and Y is Cl.

In some embodiments, the etch-priming reactant may have a structure according to Formula (VI),

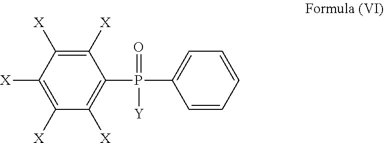

In Formula (VI), Y is selected from a group consisting of Cl, F, Br, I and NR′₂, wherein each R′ is independently H or a C1 to C3 alkyl; and each X is selected independently from a group consisting of H, Cl, F, Br and I, such that at least one X is a halogen (i.e., not H). In some embodiments, at least one X is F and Y is Cl.

For example, the etch-priming reactant according to Formula (II) may be Cl—(C═O)—CH₂—CF₃, or Cl—(C═O)—CF₃, or Cl—(C═O)—PhF₅, (Ph denotes a phenyl ring). In another example, the etch-priming reactant according to Formula (III) may be Cl—(S═O)—CH₂—CF₃, or Cl—(S═O)—CF₃, or Cl(S═O)—PhF₅. In a further example, the etch-priming reactant according to Formula (IV) may be Cl—(S(═O)₂)—CH₂—CF₃, or Cl—(S(═O)₂)—CF₃, or Cl—(S(═O)₂)—PhF₅. In yet another embodiment, the etch-priming reactant according to Formula (V) may be Cl₂—(P═O)—CH₂—CF₃, or Cl₂—(P═O)—CF₃, or Cl₂—(P═O)—Ph F₅.

In some embodiments, the etch-priming reactant may have the Formula (VII),

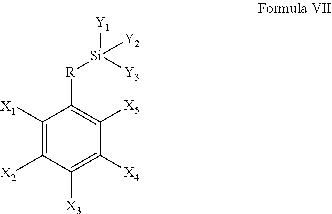

wherein X is selected from F, Cl, Br and I, R is a C1 to C6 aliphatic hydrocarbon, such as a C3 to C6 aliphatic hydrocarbon, and Y is selected from a group consisting of F, Cl, Br, I and NR′₂, wherein R′ is H or a C1 to C3 alkyl. In some embodiments, all X and all Y, respectively, are the same, with the proviso that at least one X is a halogen. For example, R may be —CH₂— (Formula VIII), or —CH₂—CH₂— (Formula IX), or —CH₂—CH₂—CH₂— (Formula X), or —CH(CH₃)—CH₂— (Formula XI), or —CH(CH₂—CH₃)— (Formula XII). In some embodiments, X is F and Y is Cl. In some embodiments, X is F and Y is Br. In some embodiments, X is F and Y is I. In some embodiments, X is Cl and Y is Br. In some embodiments, X is Cl and Y is F. In some embodiments, X is F and Y is Br. In some embodiments, X is F and Y is F. In some embodiments, X is Cl and Y is Cl. In some embodiments, the alkyl linker comprises one or more halogen atoms.

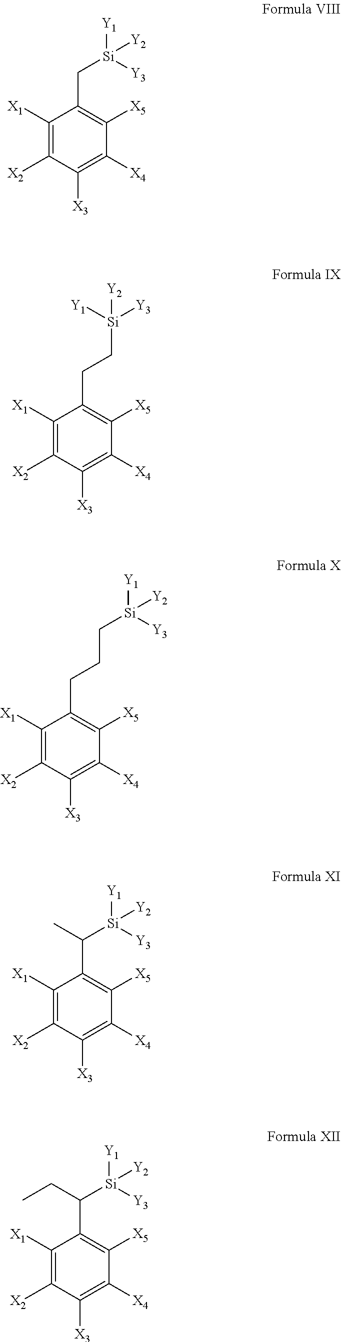

In some embodiments, the etch-priming reactant may comprise 1,2,3,4,5-pentafluoro-6-[1-(trichlorosilyl)propyl]benzene (CAS nro 1233509-66-4). In some embodiments, the etch-priming reactant may comprise 1,2,3,4,5-pentafluoro-6-[3-(trichlorosilyl)propyl]benzene (CAS nro 78900-02-4). In some embodiments, the etch-priming reactant may comprise trichloro(1H,1H,2H,2H-perfluorooctyl)silane (CF₃(CF₂)₅CH₂CH₂SiCl₃).

### Plasma

In the methods according to the current disclosure, plasma is used to generate reactive species. The reactive species can be generated from RF-generated plasma. The reactive species can be generated from, for example, inductively coupled plasma (ICP), capacitively coupled plasma (CCP), or microwave plasma. Reactive species according to the current disclosure may comprise ions, radicals or both.

In some embodiments, the reactive species are generated from a hydrogen-containing plasma. In some embodiments, the reactive species are generated from a nitrogen-containing plasma. In some embodiments, the reactive species are generated from a noble gas-containing plasma. In some embodiments, the reactive species are generated from argon-containing plasma. In some embodiments, the reactive species are generated from helium-containing plasma. In some embodiments, the reactive species are generated from krypton-containing plasma. In some embodiments, the reactive species are generated from xenon-containing plasma. In some embodiments, the reactive species are generated from plasma containing hydrogen and nitrogen. In some embodiments, the reactive species are generated from plasma containing a noble metal and nitrogen. In some embodiments, the reactive species are generated from plasma containing argon and nitrogen. In some embodiments, the reactive species are generated from plasma containing helium and nitrogen. In some embodiments, the reactive species are generated from plasma containing krypton and nitrogen. In some embodiments, the reactive species are generated from plasma containing xenon and nitrogen.

In some embodiments, plasma is generated from a gas containing substantially only hydrogen. In some embodiments, plasma is generated from a gas containing substantially only nitrogen. In some embodiments, plasma is generated from a gas containing substantially only a noble gas. In some embodiments, plasma is generated from a gas containing substantially only argon. In some embodiments, plasma is generated from a gas containing substantially only helium. In some embodiments, plasma is generated from a gas containing substantially only nitrogen and hydrogen. In some embodiments, plasma is generated from a gas containing substantially only nitrogen and a noble metal. In some embodiments, plasma is generated from a gas containing substantially only nitrogen and argon.

Plasma power of RF-generated can be varied in different embodiments of the current disclosure. In some embodiments, plasma is generated by applying RF power of from about 10 W to about 1,000 W, or from about 50 W to about 1,000 W, or from about 100 W to about 500 W. In some embodiments the RF power density may be from about 0.02 W/cm² to about 2.0 W/cm², or from about 0.05 W/cm² to about 1.5 W/cm². The RF power may be applied to a gas that flows during the plasma pulse time, that flows continuously through the reaction chamber, and/or that flows through a remote plasma generator. Thus, in some embodiments, radical species may be formed remotely via plasma discharge (“remote plasma”) away from the substrate or reaction space. In some embodiments, radical species may be formed in the vicinity of the substrate or directly above substrate (“direct plasma”). In some embodiments, plasma power is 50 W.

### Etching Cycle

In some embodiments, methods according to the current disclosure comprise one or more etching cycles. Each etching cycle may comprise providing an etch-priming reactant into the reaction chamber and providing radical species generated by plasma into the reaction chamber. An etching cycle may comprise removing excess reactant and/or reaction by-products, if any, from the reaction chamber. Said removal may be performed as a purging step. In some embodiments the etching cycle is repeated two or more times. In some embodiments, the etching cycle is repeated immediately after the previous cycle has been completed, i.e., there are no additional process steps between the two etching cycles.

Without limiting the current disclosure to any specific theory, the etch-priming reactant may be beneficial in regulating the etching process according to the current disclosure. In some embodiments, it may be possible to regulate the density of the etch-priming reactant on the first surface by adjusting the length of the time etch-priming reactant is present in the reaction chamber, i.e., the pulse time of the etch-priming reactant. Additionally, the chemisorption of the etch-priming reactant to the substrate surface may be regulated by substrate temperature, and by adjusting the concentration of the etch-priming reactant in the vicinity of the substrate through gas flow and use of diluting gases, for example. The density of the etch-priming reactant on the substrate surface may be proportional to the speed and/or degree of etching on the first surface. In some embodiments, the etch-priming reactant may be deposited substantially only, or only, on the first surface of the substrate.

Additionally, the presence of the etch-priming reactant may allow, or at least, assist in, making the etching process self-limiting. Without limiting the current disclosure to any specific theory, it may be that the etch-priming reactant is removed from the first surface by plasma exposure. Once the etch-priming reactant has been removed from the first surface through plasma exposure, etching of the first surface may stop or slow down. Thus, adjusting the intensity of the plasma treatment, as well as appropriately selecting the gas from which plasma is generated, may offer another way of regulating the selective etching process according to the current disclosure.

In some embodiments, the etching cycle is incorporated into a deposition process. In some embodiments, the etching cycle is incorporated into a selective deposition process. Thus, a selective etching process according to the current disclosure may be used in combination with one or more selective and/or non-selective deposition process to achieve selective deposition on a substrate.

The method according to the current disclosure may be used in non-selective mode to etch surfaces comprising etchable material. Thus, in an aspect, a method of etching a metal or semimetal oxide, such as silicon oxide is disclosed. The method comprises providing a substrate comprising a metal or semimetal oxide into a reaction chamber, providing an etch-priming reactant into the reaction chamber in vapor phase, providing reactive species generated from plasma into the reaction chamber for etching metal or semimetal oxide, wherein the etch-priming reactant comprises a halogenated hydrocarbon. The etching process may be self-limiting. The etching cycle may be repeated to make it a cyclic etching process. What is explained above regarding the first surface applies to the metal or semimetal oxide surface of the non-selective method. Similarly, what is explained above regarding the etch-priming reactant applies to the non-selective method.

In an aspect, an assembly for processing a substrate is disclosed. The assembly comprises a reaction chamber constructed and arranged to hold the substrate, an etch-priming reactant source constructed and arranged to contain and evaporate the etch-priming reactant, a plasma generator for generating plasma, a plasma reactant source for providing a gas to the plasma generator, and a reactant injection system constructed and arranged to provide an etch-priming reactant and plasma from the plasma generator into the reaction chamber in vapor phase.

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

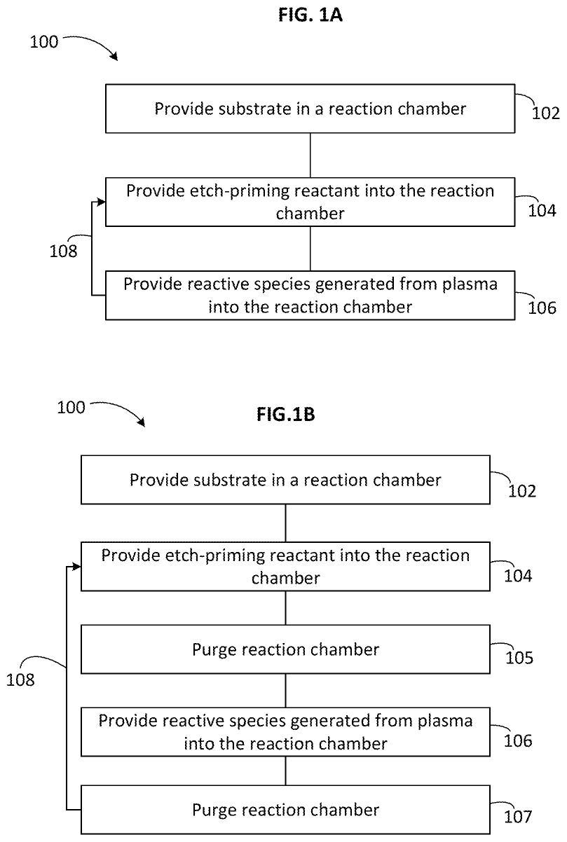

FIGS. 1A and 1B illustrate an exemplary embodiment of a selective etching method according to the current disclosure as a block diagram. Method 100 may be used to selectively etch a first material relative to a second material from a substrate. The etching method 100 can be used during a formation of a semiconductor structure or device.

During step 102, a substrate is provided into a reaction chamber of a substrate processing apparatus. The reaction chamber can form part of cluster tool. In some embodiments, the substrate processing apparatus is a single-wafer processing apparatus. Alternatively, the apparatus may be a batch processing apparatus. Various phases of method 100 can be performed within a single reaction chamber or they can be performed in multiple reactor chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. The reaction chamber can be provided with a heater to activate the reactions by elevating the temperature of one or more of the substrate and/or the reactants and/or other gases.

During step 102, the substrate can be brought to a desired temperature and pressure for providing etch-priming reactant into the reaction chamber (step 104) and/or for providing reactive species into the reaction chamber (step 106). A temperature (e.g., of a substrate or a substrate support) within a reaction chamber can be, for example, from about 20° C. to about 120° C., from about 20° C. to about 80° C., from about 20° C. to about 60° C. or from about 20° C. to about 50° C. As a further example, a temperature within a reaction chamber can be from about 30° C. to about 120° C., or from about 30° C. to about 80° C., or from about 30° C. to about 60° C., or from about 30° C. to about 55° C., or from about 40° C. to about 70° C., or from about 40° C. to about 80° C. Exemplary temperatures within the reaction chamber may be 25° C., 35° C., 45° C., 50° C., 55° C., 70° C., 90° C. or 95° C.

A pressure within the reaction chamber can be less than 760 Torr, for example less than 100 Torr, less than 50 Torr, less than 20 Torr, less than 5 Torr, less than 2 Torr, less than 1 Torr or less than 0.1 Torr. In some embodiments, a pressure within the reaction chamber is from about 0.01 Torr to about 80 Torr, or from about 0.01 Torr to about 50 Torr, or from about 0.01 Torr to about 20 Torr, or from about 0.01 Torr to about 10 Torr, or from about 0.01 Torr to about 5 Torr, or from about 0.01 Torr to about 1 Torr. Exemplary reaction chamber pressures include about 10 Torr, about 5 Torr, about 3 Torr or about 1 Torr, or about 0.5 Torr or about 0.1 Torr. Different pressure may be used for different process steps. In some embodiments, the pressure is the same throughout the process.

Etch-priming reactant is provided into the reaction chamber containing the substrate at step 104. Without limiting the current disclosure to any specific theory, the etch-priming reactant may chemisorb on the first surface of the substrate during providing the etch-priming reactant into the reaction chamber. In some embodiments, the etch-priming reactant does not chemisorb on the second surface. In some embodiments, the etch-priming reactant chemisorbs to the second surface to a lesser extent than to the first surface. The duration of providing etch-priming reactant into the reaction chamber (etch-priming reactant pulse time) may be, for example, from about 5 seconds to about 20 minutes. The duration of providing etch-priming reactant into the reaction chamber is selected based on the process, tool and other factors. In some embodiments, duration of providing etch-priming reactant into the reaction chamber is from about 5 seconds to about 2 minutes, or from about 5 seconds to about 90 seconds, or from about 5 seconds to about 60 seconds. In some embodiments, duration of providing etch-priming reactant into the reaction chamber is from about 15 seconds to about 5 minutes, or from about 15 seconds to about 3 minutes, or from about 15 seconds to about 2 minutes, or from about 10 seconds to about 90 seconds. In some embodiments, the duration of providing etch-priming reactant into the reaction chamber (etch-priming reactant pulse time) is may be longer than 5 seconds or longer than 10 seconds or longer than 30 seconds, or longer than 60 seconds. In some embodiments, the duration of providing etch-priming reactant into the reaction chamber (etch-priming reactant pulse time) is may be shorter than about 15 minutes or shorter than about 10 minutes or shorter than about 5 minutes, or shorter than about 3 minutes, or shorter than about 60 seconds, or shorter than about 30 seconds. Alternatively, purge time after etch-priming reactant pulse may be from about 0.1 seconds to about 120 seconds, or from about 0.1 seconds to about 60 seconds, or from about 0.1 seconds to about 30 seconds, or from about 0.1 seconds to about 10 seconds, or from about 0.1 seconds to about 5 seconds, or from about 0.1 seconds to about 2 seconds, or from about 0.1 seconds to about 1 second, or from about 0.1 seconds to about 0.5 seconds. In some embodiments, the purge time after etch-priming reactant is shorter than 60 seconds, shorter than 30 seconds, shorter than 10 seconds, shorter than 4 seconds, shorter than 1 seconds, or shorter than 0.5 seconds.

Reactive species generated from plasma are provided into the reaction chamber at step 106. The reactive species may react with the chemisorbed etch-priming reactant, or its derivate species, to form species etching the material of the first surface. The etching species may be generated locally to bring about etching only, or substantially only, in the areas in which the etch-priming reactant is present. Alternatively or in addition, the reactive species generated from plasma may bring about etching directly. In some embodiments, the etch-priming reactant reacts to the reactive species to a lesser extent on the second surface than on the first surface. The duration of providing reactive species from plasma into the reaction chamber (plasma pulse time) may be, for example from about 0.1 seconds to about 5 minutes, or from about 0.1 seconds to about 3 minutes, or from about 0.1 seconds to about 1 minute, or from about 0.1 seconds to about 30 seconds, or from about 0.1 seconds to about 10 seconds. In some embodiments, a plasma pulse time is from about 1 second to about 5 minutes, or from about 1 second to about 3 minutes, or from about 1 second to about 60 seconds, or from about 1 second to about 30 seconds. In some embodiments, the plasma pulse time is about 0.5 seconds, about 1 second, about 3 seconds, about 5 seconds, about 10 seconds, about 15 seconds, about 25 seconds, about 30 seconds, about 45 seconds or about 60 seconds. In some embodiments, the duration of providing reactive species from plasma into the reaction chamber is shorter than about 60 seconds, shorter than about 30 seconds, shorter than about 10 seconds, or shorter than about 5 seconds. Conversely, in some embodiments, a minimum duration for the plasma pulse may be defined. For example, the plasma pulse time may be longer than about 40 seconds, longer than about 25 seconds, longer than about 15 seconds, longer than about 8 seconds, longer than about 5 seconds, or longer than about 0.5 seconds.

In some embodiments, the etch-priming reactant may be heated before providing it into the reaction chamber. In some embodiments, the etch-priming reactant may kept in ambient temperature before providing it to the reaction chamber.

Steps 104 and 106, may form an etching cycle, resulting in etching material of the first surface. In some embodiments, the two steps of selective etching according to the current disclosure, namely providing the etch-priming reactant and reactive species generated from plasma into the reaction chamber (104 and 106), may be repeated (loop 108). Such embodiments contain several etching cycles. The amount of material etched from the first surface may be regulated by adjusting the number of deposition cycles and/or parameters during etching. The etching cycle (loop 108) may be repeated until a desired amount of material is removed. For example, one, two, three, four or five etching cycles may be performed. In some embodiments, about 10, about 20, about 50 or about 100 etching cycles may be performed. In some embodiments, the etching process according to the current disclosure is started by first providing etch-priming reactant into the reaction chamber 104, and thereafter providing reactive species generated from plasma into the reaction chamber 106. However, embodiments can be envisaged in which reactive species generated from plasma are first provided into the reaction chamber (106), and etch-priming reactant is provided thereafter (104). For example, reactive species may be used to clean or otherwise condition the substrate surfaces for etching.

The amount of material removed during one etching cycle varies depending on the process conditions, such as the etch-priming reactant, ion energy and substrate temperature. In some embodiments, material is removed from the first surface at a rate of about 0.3 Å/cycle to about 25 Å/cycle. In some embodiments, etching rate of the material from the first surface may be, for example, from about 2 Å/cycle to about 20 Å/cycle, whereas in some other embodiments, the etching rate may be, for example from about 3 Å/cycle to about 20 Å/cycle, or from about 3 Å/cycle to about 15 Å/cycle. For example, the etch rate may be about 1 Å/cycle, or about 5 Å/cycle, or about 8 Å/cycle, or about 12 Å/cycle. Depending on the etching conditions, etching cycle numbers etc., variable depth of material may be removed by etching. The desired etching depth achieved by the method according to the current disclosure may be selected based on the application in question.

Etch-priming reactant and reactive species generated from plasma may be provided into the reaction chamber in separate steps (104 and 106). FIG. 1B illustrates an embodiment according to the current disclosure, where steps 104 and 106 are separated by purge steps 105 and 107. In such embodiments, an etching cycle comprises one or more purge steps 105, 107. During purge steps, etch-priming reactant and/or reactive species generated from plasma can be temporally separated from each other by inert gases, such as argon (Ar), nitrogen (N₂) or helium (He) and/or a vacuum pressure. The separation of etch-priming reactant and reactive species may alternatively be spatial.

Purging the reaction chamber 105, 107 may prevent or mitigate gas-phase reactions between the etch-priming reactant and reactive species generated from plasma, and improve process efficiency and specificity. Surplus reactant and/or reaction byproducts and/or decomposition products, if any, may be removed from the substrate surface, such as by purging the reaction chamber or by moving the substrate, before the process is continued. In some embodiments, however, the substrate may be moved to separately contact an etch-priming reactant and reactive species generated from plasma. Because in some embodiments, the reactions may be self-limiting, precise dosage control of the reactant and reactive species may not be required.

In some embodiments, the etch-priming reactant is brought into contact with a substrate surface at step 104, excess etch-priming reactant is partially or substantially completely removed by an inert gas or vacuum at step 105, and reactive species generated from plasma are brought into contact with the substrate surface comprising etch-priming reactant. The etch-priming reactant may be present only, or substantially only, on the first surface of the substrate. Etch-priming reactant may be brought in to contact with the substrate surface in one or more pulses 104. In other words, pulsing of the etch-priming reactant 104 may be repeated. The etch-priming reactant on the substrate surface may react with the reactive species generated from plasma to etch the material of the first surface of the substrate. Also pulsing of plasma to generate reactive species at step 106 may be repeated. In some embodiments, reactive species may be provided in the reaction chamber first 106. Thereafter, the reaction chamber may be purged 105 and etch-priming reactant provided in the reaction chamber in one or more pulses 104.

The selective etching process according to the current disclosure may comprise additional pre- or post-treatment steps. For example, the substrate may be cleaned before the beginning of the process through thermal, plasma or chemical cleaning process. Any residual etch-priming reactant, reaction by-products or decomposition residues may be removed from the reaction chamber after etching process by a separate purge step, or through thermal, chemical or plasma cleaning.

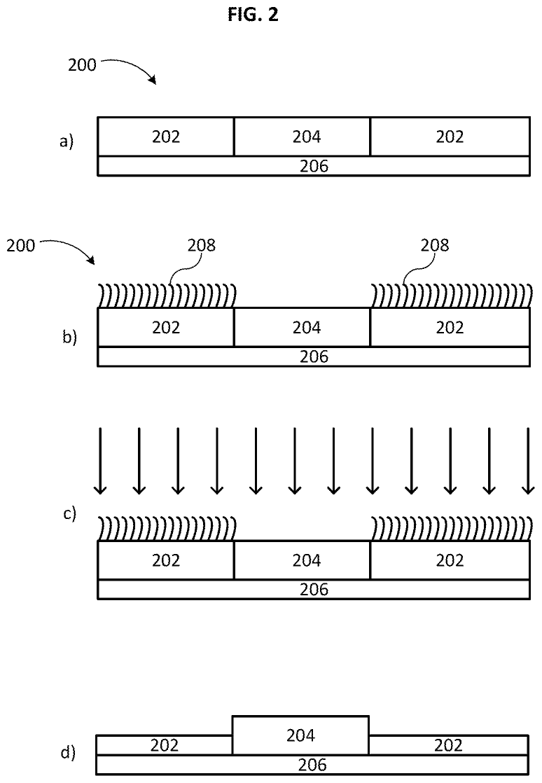

FIG. 2 illustrates an exemplary method 200 of selectively etching material from a first surface 202 of a substrate relative to a second surface 204 of the substrate. Panel a) depicts a substrate 206 comprising a first surface 202 and a second surface 204. In the example of FIG. 2, the first surface 202 and the second surface 204 are positioned on bulk substrate material 206. Additionally, although the two surfaces 202, 204 are depicted to be in one plane, the two surfaces may be on different vertical levels, or have variable topologies.

In panel b), etch-priming reactant 208 has been deposited on the first surface 202. Panel c) illustrates providing reactive species generated from plasma into to the reaction chamber. Thus, reactive species are contacted with the substrate, and the presence of the etch-priming reactant 208 on the first surface 202 will cause selective etching of the first surface 202, as depicted in panel d). Although not indicated in the schematic illustration of FIG. 2, some material from the second surface 204 may be etched, too. However, the rate of etching of the second surface 204 is lower than that of the first surface 202. The difference in the etching rate between first surface 202 and second surface 204 depends on the process parameter and materials used. In some embodiments, the first surface 202 comprises, consists essentially of, or consists of silicon oxide, and the second surface 204 comprises, consists essentially of, or consists of silicon nitride.

In a non-limiting example, a silicon oxide surface may be selectively etched relative to a silicon nitride surface. The substrate temperature may be kept at 50° C., while the reactant source may be kept at ambient temperature. The pressure in the reaction chamber may be from 0.01 Torr to about 2.5 Torr during the process. The etch-priming reactant may be provided into the reaction chamber from about 30 seconds to about 5 minutes. The etch-priming reactant may comprise perfluoro-octylsilane (POCS). The reaction chamber may be purged after providing the etch-priming reactant into the reaction chamber. Then, argon plasma may be provided into the reaction chamber. The RF power used for plasma generation may be from about 30 W to about 100 W, such as 50 W. The plasma may be kept on from about 30 seconds to about 2 minutes. However, if the frequency of plasma generation is, for example, 13.56 MHZ, and pressure is higher, the duration of plasma treatment may be much shorter, such as from 0.1 seconds to 30 seconds. The reaction chamber may be purged after providing the reactive species into the reaction chamber. For example, about 1 nm of silicon oxide may be etched in each etch cycle.

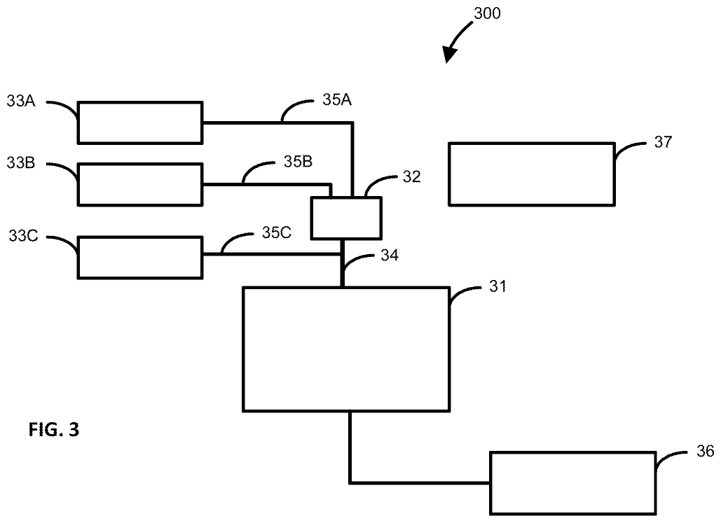

FIG. 3 illustrates an exemplary embodiment of a substrate processing assembly 300 according to the current disclosure in a schematic form. As a schematic representation of an substrate-processing assembly, many components have been omitted for simplicity of illustration, and such components may include, for example, various valves, manifolds, purifiers, heaters, containers, vents, and/or bypasses.

The substrate processing assembly 300 may comprise a reaction chamber 31, a plasma generator 32, a plasma reactant source 33A for providing gas for generating radical species from plasma, an inert gas source 33B, an etch-priming reactant source 33C, a pathway 34 disposed between the remote plasma unit 32 and the reaction chamber 31, and gas lines 35A-35C linking the sources 33A-33C with a reaction chamber 31. In the embodiment of FIG. 3, the plasma generator 32 is a remote plasma unit. In some embodiments, a substrate processing system may comprise multiple plasma generators 32 (e.g., one coupled to a hydrogen source for producing a hydrogen radical, and one coupled to a nitrogen source for producing a nitrogen radical). In the exemplary embodiment of FIG. 3, the substrate processing assembly 300 comprises two gas sources 33A, 33B, in addition to the etch-priming reactant source 33C. Both gas sources 33A and 33B are connected to the reaction chamber 31 through the plasma generator 32, so they may be considered plasma reactant sources, but depending on the process specifics, one (or more in case there are more gas sources) of gas lines may bypass the plasma generator 32. The pathway 34 and gas lines 35A-35C, together with the necessary valves, manifolds, etc., constitute a reactant injection system to provide an etch-priming reactant and plasma from the plasma generator into the reaction chamber in vapor phase.

FIG. 3 additionally illustrates an exhaust gas source 36. An exhaust source 36 may comprise one or more vacuum pumps. The embodiment of a substrate processing assembly additionally comprises and a controller 37. The controller 37 includes electronic circuitry and software to selectively operate valves, manifolds, heaters, pumps and other components included in the substrate processing assembly 300. Such circuitry and components operate to provide etch-priming reactant and other gases, regulate temperature etc. to provide proper operation of the substrate processing assembly 300. Controller 37 can include modules such as a software or hardware component, which performs certain tasks. A module may be configured to reside on the addressable storage medium of the control system and be configured to execute one or more processes.

The substrate processing assembly of FIG. 3 may be a part of a cluster tool comprising multiple reaction chambers. The reaction chamber 310 may be an individual processing station of a multi-station tool. In some embodiments, the substrate processing assembly comprises a hot-wall, cold-wall or warm-wall type of reaction chamber.

During operation of substrate processing assembly 300, substrates, such as semiconductor wafers (not illustrated), are transferred from, e.g., a substrate handling system to reaction chamber 31. Once substrate(s) are transferred to reaction chamber 31, one or more gases from gas sources 33A-33C, such as etch-priming reactant, gases for generating reactive species and/or purge gases, are introduced into reaction chamber 31.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively etching material from a first surface of a substrate relative to a second surface of the substrate, the method comprising:
providing a substrate comprising the first surface and the second surface into a reaction chamber;
providing an etch-priming reactant into the reaction chamber in vapor phase; and
providing reactive species generated from plasma into the reaction chamber for selectively etching material from the first surface;
wherein the etch-priming reactant is deposited on the first surface; and wherein the etch-priming reactant comprises a halogenated hydrocarbon.

2. The method of claim 1, wherein the selective etching process is a cyclic etching process.

3. The method of claim 1, wherein the selective etching process is a self-limiting process.

4. The method of claim 1, wherein the etch-priming reactant and the reactive species are provided into the reaction chamber alternately and sequentially.

5. The method of claim 1, wherein the reaction chamber is purged after providing etch-priming reactant and/or after providing reactive species into the reaction chamber.

6. The method of claim 1, wherein the first surface comprises oxygen.

7. The method of claim 6, wherein the first surface comprises an oxide.

8. The method of claim 1, wherein the second surface comprises nitrogen.

9. The method of claim 8, wherein the second surface comprises a nitride.

10. The method of claim 8, wherein the second surface comprises nitrogen and hydrogen.

11. The method of claim 1, wherein the second surface does not comprise oxygen.

12. The method of claim 1, wherein the etch-priming reactant comprises a head group and a tail group.

13. The method of claim 12, wherein the head group contains a third-row semimetal or non-metal.

14. The method of claim 13, wherein the third-row semimetal or non-metal is selected from a group consisting of silicon, phosphorus and sulfur.

15. The method of claim 12, wherein the head group comprises an oxygen atom connected to the rest of the molecule through a double bond.

16. The method of claim 12, wherein the head group comprises an amine group.

17. The method of claim 12, wherein the head group comprises a halogen atom.

18. The method of claim 17, wherein the halogen atom is attached to the third-row non-metal or semimetal.

19. The method of claim 18, wherein the head group comprises a halosilane.

20. The method of claim 1, wherein the etch-priming reactant comprises an aromatic hydrocarbon.

21. The method of claim 1, wherein the halogenated hydrocarbon is selected from fluorinated hydrocarbons, chlorinated hydrocarbons, brominated hydrocarbons and iodinated hydrocarbons.

22. The method of claim 1, wherein the etch-priming reactant forms a self-assembled monolayer on the first surface.

23. A method of selectively etching material from a first surface of a substrate relative to a second surface of the substrate, the method comprising an etch process comprising forming an etch-priming layer on the first surface using a halosilane compound comprising an aromatic hydrocarbon.

24. The method of claim 23, wherein the aromatic portion of the hydrocarbon is halogenated.

25. An assembly for processing a substrate comprising:
a reaction chamber constructed and arranged to hold the substrate;
an etch-priming reactant source constructed and arranged to contain and evaporate the etch-priming reactant;
a plasma generator for generating plasma;
a plasma reactant source for providing a gas to the plasma generator; and
a reactant injection system constructed and arranged to provide an etch-priming reactant and plasma from the plasma generator into the reaction chamber in vapor phase.

26. The assembly of claim 25, wherein the reaction chamber is an etching chamber constructed and arranged to vapor-phase etching of a semiconductor substrate.
